(19) United States
(12) Patent Application Publication
(10) Pub. No.: US 2019/0362989 A1
(43) Pub. Date: Nov. 28, 2019

(54) SUBSTRATE MANUFACTURING APPARATUS AND METHODS WITH FACTORY INTERFACE CHAMBER HEATING

(71) Applicant: Applied Materials, Inc., Santa Clara, CA (US)

(72) Inventors: Paul B. Reuter, Austin, TX (US); Nir Merry, Mountain View, CA (US); Michael R. Rice, Pleasanton, CA (US); Dean C. Hruzek, Cedar Park, TX (US)

(21) Appl. No.: 16/420,487

(22) Filed: May 23, 2019

Related U.S. Application Data
(60) Provisional application No. 62/676,731, filed on May 25, 2018.

(51) Int. Cl. H01L 21/67; H01L 21/677; B01D 46/42

(52) U.S. Cl. CPC H01L 21/67017; H01L 21/67248; H01L 21/67196; B01D 2279/35; H01L 21/67109; B01D 46/4263; H01L 21/67763

(57) ABSTRACT

Electronic device processing apparatus including a factory interface chamber purge apparatus with purge gas heating. The factory interface chamber purge apparatus includes one or more heating elements configured to heat the purge gas. In some embodiments, the provision of heated purge gas to the chamber filter assembly can rapidly reduce moisture contamination after the access door is opened for factory interface servicing. In further embodiments, the provision of heated purge gas to the factory interface chamber can aid in desorbing certain chemical compounds from the substrates following processing when a low-humidity environment is provided. Purge control methods and apparatus are described, as are numerous other aspects.

### RELATED APPLICATIONS

This application claims the benefit of U.S. Provisional Application No. 62/676,731, filed May 25, 2018, the entire contents of which are incorporated herein by reference.

### FIELD

Embodiments relate to electronic device manufacturing, and more specifically to factory interface apparatus and methods including environmental control. Related Applications.

### BACKGROUND

Processing of substrates in semiconductor component manufacturing is carried out in process tools. Substrates travel between the process tools in substrate carriers (e.g., Front Opening Unified Pods or FOUPs), which can dock to a factory interface of the tool, otherwise referred to as an equipment front end module (EFEM). The factory interface includes a factory interface chamber that can contain a load/unload robot that is operable to transfer substrates between the respective FOUPs docked at a load port of the factory interface and one or more load locks or process chambers, for example. In some vacuum tools, substrates pass directly between the substrate carrier and a process chamber through the factory interface chamber, while in other embodiments the substrates can pass through the factory interface chamber and between the substrate carrier and a load lock and then into a processing chamber for processing.

Recently, there has been a move in the semiconductor processing industry to control the environment within the factory interface, such as by supplying a purge gas (e.g., an inert gas) into the factory interface chamber and/or into the wafer FOUPs. However, such systems can suffer from certain performance problems.

Accordingly, factory interface apparatus and factory interface operating methods comprising improved processing capability are desired.

### SUMMARY

In one aspect, a factory interface purge apparatus is provided. The factory interface purge apparatus includes a factory interface chamber including a purge gas, and one or more heating members configured to heat the purge gas in factory interface chamber.

In another aspect, a chamber filter purge apparatus is provided. The chamber filter purge apparatus includes a factory interface chamber including an access door, a chamber filter assembly configured to filter purge gas provided in the factory interface chamber, and a purge gas heating apparatus comprising one or more heating elements configured to heat the purge gas provided to the chamber filter assembly.

In a method aspect, a purge control method is provided. The purge control method includes providing a factory interface chamber having an access door configured to provide personnel servicing access into the factory interface chamber, closing the access door, providing flow of a purge gas to the factory interface chamber, and commencing heating of the purge gas. The method can include ceasing or reducing purge gas heating when a pre-established condition is reached.

Numerous other aspects are provided in accordance with these and other embodiments of the disclosure. Other features and aspects of embodiments of the present disclosure will become more fully apparent from the following detailed description, the accompanying drawings, and the claims.

### BRIEF DESCRIPTION OF THE DRAWINGS

The drawings, described below, are for illustrative purposes only and are not necessarily drawn to scale. The drawings are not intended to limit the scope of the disclosure in any way.

FIG. 1 illustrates a schematic top view of an electronic device processing apparatus including a factory interface apparatus with purge gas heating according to the disclosure.

FIG. 2 illustrates a first partially cross-sectioned side view of an electronic device processing apparatus including a factory interface apparatus with purge gas heating according to the disclosure.

FIG. 3 illustrates another partially cross-sectioned side view of an electronic device processing apparatus including a factory interface apparatus with purge gas heating according to the disclosure.

FIG. 4A illustrates a partially cross-sectioned side view of an electronic device processing apparatus including a first alternative embodiment of a factory interface apparatus including purge gas heating within a plenum chamber according to the disclosure.

FIG. 4B illustrates a perspective view of an embodiment of a purge gas heating apparatus shown in isolation according to the disclosure.

FIG. 5A illustrates another partially cross-sectioned side view of an electronic device processing apparatus including a second alternative embodiment of a factory interface apparatus including purge gas heating in a return flow path according to the disclosure.

FIG. 5B illustrates a partial perspective view of purge gas heating elements provided in a return flow path according to the disclosure.

FIG. 6 illustrates another partially cross-sectioned side view of an electronic device processing apparatus including a second alternative embodiment of a factory interface apparatus with purge gas heating via heating a filter assembly according to the disclosure.

FIG. 7 illustrates a flowchart depicting a gas heating method for a factory interface chamber according to one or more embodiments.

FIG. 8 illustrates a flowchart depicting a purge control method for a factory interface chamber according to one or more embodiments.

### DETAILED DESCRIPTION

Reference will now be made in detail to the example embodiments, which are illustrated in the accompanying drawings. Wherever possible, the same or like reference numbers will be used throughout the drawings to refer to the same or like parts throughout the several views. Features shown in the various embodiments herein can be combined with each other unless specifically noted otherwise.

Existing electronic device manufacturing systems may suffer from problems when a high relative humidity level, high oxygen (O₂) level, and/or a high level of other chemical contaminant are observed. In particular, exposure of substrates to relatively high humidity levels, relatively high O₂ levels, and/or other chemical contaminants and particulates can adversely affect substrate properties.

Accordingly, certain electronic device processing apparatus provide efficiency and/or processing improvements in the manufacturing of substrates by controlling certain environmental conditions to which the substrates are exposed to when in transit through the factory interface chamber. The factory interface receives substrates from one or more substrate carriers docked to a wall thereof (e.g., docked to a front wall thereof) and a load/unload robot can deliver the substrates for processing, such as to another opening (e.g., one or more load locks) in another wall of the factory interface (e.g., a rear wall thereof). In such factory interfaces with environmental control, a purge gas such as an inert gas can be supplied to the factory interface chamber to purge the oxygen, moisture, and/or contaminants from the factory interface chamber.

One or more environmental parameters (e.g., relative humidity, an amount of O₂, an amount of an inert gas, or an amount of a chemical contaminant can be monitored and controlled by supplying the purge gas to the factory interface chamber. Opening of the respective FOUPs docked to the factory interface wall can be delayed until certain pre-conditions regarding one or more of the above-listed constituents in the environment of a factory interface chamber are met.

However, even when constituents such as relative humidity (RH), oxygen levels and/or levels of contaminants are controlled to be below pre-designated amounts within the factory interface chamber, other problems can arise. For example, because of the relatively-low humidity environment, it may then be quite difficult to desorb certain contaminants from the surfaces of the substrates. Such contaminants can be present there due to processing, such as when processing occurs at temperatures above 300° C., for example.

For example, as a result of processing certain halogen gases can react vigorously with Silicon of the substrates to form silicon tetrahalides. In particular, Silicon can react with fluorine (F₂), chlorine (Cl₂), and/or bromine (Br₂), to form respectively silicon tetrafluoride (SiF₄), silicon tetrachloride (SiCl₄), and/or silicon tetrabromide (SiBr₄). The organic compound silicon tetrabromide (SiBr₄) can be particular difficult to desorb, especially in the relative absence of water vapor due to the relatively-low humidity levels provided by control of the environmental within the factory interface chamber.

Thus, a factory interface apparatus and purge control methods that can adequately desorb halogen compounds, such as silicon tetrafluoride (SiF₄), silicon tetrachloride (SiCl₄), and/or particularly silicon tetrabromide (SiBr₄) from the substrate would be considered a substantial advancement in the art.

Furthermore, the factory interface chamber may be accessed by service personnel for servicing various components within the factory interface chamber, such as load port door openers, load/unload robot, slit valves, other factory interface chamber components, and the like. During such service intervals, an access door to the factory interface chamber is opened allowing the service personal to enter and perform the service. The flow of the purge gas is ceased during such servicing intervals.

As a result, a chamber filter assembly that is configured to filter particulates and possibly absorb certain chemicals from the purge gas can become appreciably contaminated with moisture during the service interval where the access door is open. This is because ambient air from the factory environment can contain moisture, sometimes as high as 40% relative humidity at room temperature (RT). Once contaminated with moisture, it can take an extended period of time to purge the chamber filter assembly, sometimes as long as 24 hours. Thus, the tool can be offline for extended periods after performing service. Moreover large amounts of purge gas can be dumped to an exhaust to accomplish this extended purge. Thus, the cost and time to purge the factory interface chamber to the condition where tool operation can be restarted can be excessive.

To ameliorate one or more of the problems listed above, and in particular, to 1) aid in desorbing certain chemical compounds, such as halogen-containing compounds from the substrates and/or 2) to aid in reducing the time to purge moisture contamination from the chamber filter assembly caused by service, factory interface purge apparatus including purge gas heating and purge control methods are provided by the present disclosure. As a result, down time and purge cost can be substantially reduced and/or substrate quality can be improved.

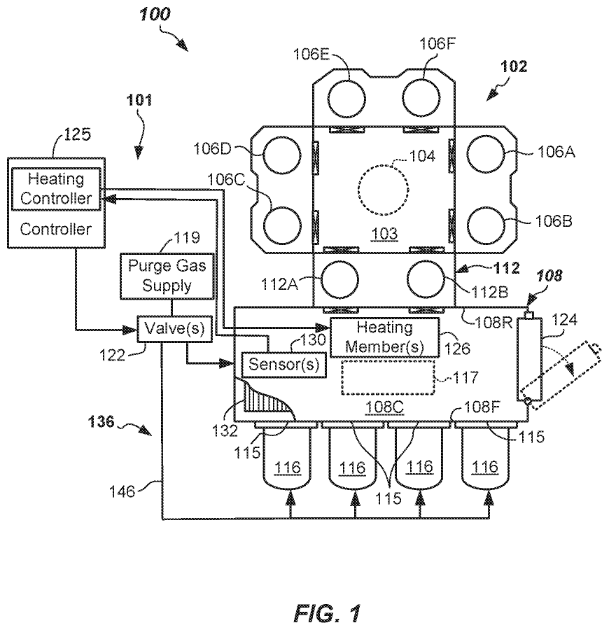

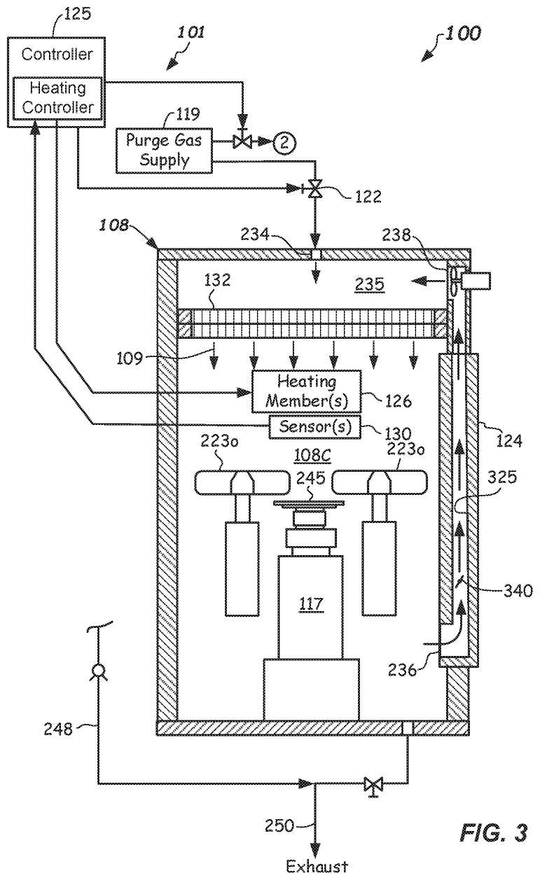

Further details of example factory interface purge apparatus, factory interface purge apparatus including purge gas heating, and purge control methods are described with reference to FIGS. 1-8 illustrated herein.

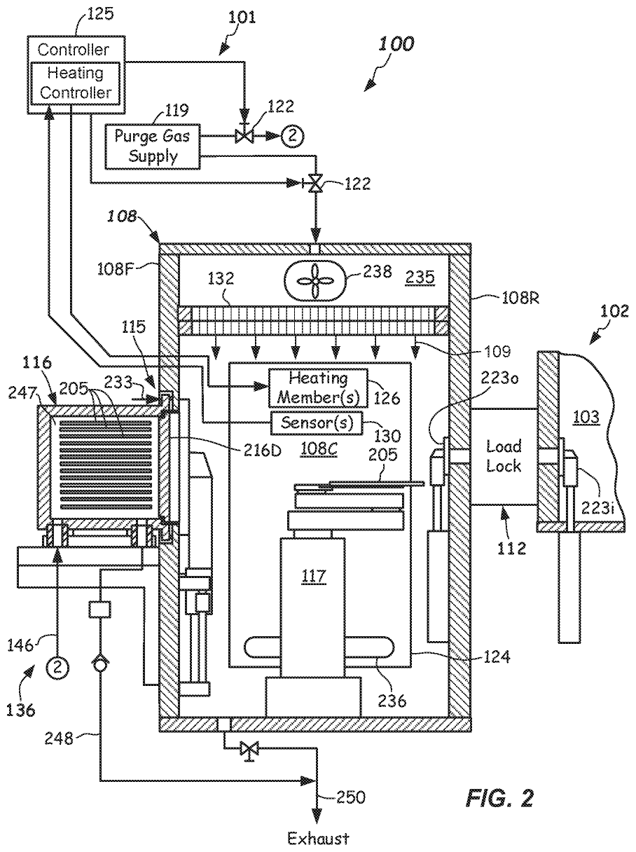

FIGS. 1-3 illustrate schematic diagrams of a first example embodiment of an electronic device processing apparatus 100 including a factory interface purge apparatus 101 according to one or more embodiments of the present disclosure. The electronic device processing apparatus 100 may include a processing portion 102 configured to process substrates 205 (FIG. 2) therein. The processing portion 102 can include mainframe housing having housing walls defining a transfer chamber 103. A transfer robot 104 (shown as a dotted circle in FIG. 1) may be at least partially housed within the transfer chamber 103. The transfer robot 104 may be configured and adapted to place or extract substrates 205 to and from process chambers 106A-106F via its operation. Substrates 205 as used herein shall mean articles used to make electronic devices or circuit components, such as silica-containing discs or wafers, patterned or masked wafers, silica-containing plates, or the like.

Transfer robot 104, in the depicted embodiment, may be any suitable type of robot adapted to service the various chambers (such as twin chambers shown) coupled to and accessible from the transfer chamber 103, such as the robot disclosed in US Patent Pub. No. 2010/0178147, for example. Other robot types may be used. Moreover, other mainframe configurations than the twinned chamber configuration shown may be used. Furthermore, in some embodiments, the substrates 205 may be placed directly into a process chamber, i.e., where there is no transfer chamber 103.

In the case where there is a transfer chamber 103, the motion of the various arm components of the transfer robot 104 may be controlled by suitable commands to a drive assembly (not shown) containing a plurality of drive motors of the transfer robot 104 as commanded from a robot controller (not shown). Signals from the robot controller cause motion of the various components of the transfer robot 104. Suitable feedback mechanisms may be provided for one or more of the components by various sensors, such as position encoders, or the like.

The transfer chamber 103 in the depicted embodiment may be generally square or slightly rectangular in shape. However, other suitable shapes of the mainframe housing such as octagonal, hexagonal, heptagonal, octagonal, and the like can be used. Further other numbers of facets and processing chambers are possible. The destinations for the substrates 205 may be one or more of the process chambers 106A-106F, which may be configured and operable to carry out one or more processes on the substrates 205 delivered thereto. The processes carried out by process chambers 106A-106F may be any suitable process such as plasma vapor deposition (PVD) or chemical vapor deposition (CVD), etch, annealing, pre-clean, metal or metal oxide removal, or the like. Other processes may be carried out on substrates 205 therein.

The electronic device processing apparatus 100 can further include a factory interface apparatus 108 that includes environmental controls. Factory interface apparatus 108 includes a housing with walls forming a sealed enclosure. Substrates 205 may be received into the transfer chamber 103 from the factory interface apparatus 108, and also exit the transfer chamber 103 into the factory interface apparatus 108 after processing thereof. Entry and exit to the transfer chamber 103 may be through an opening, or if a vacuum tool, through a load lock 112 that is coupled to a wall (e.g., a rear wall 108R) of the factory interface apparatus 108. The load lock 112 may include one or more load lock chambers (e.g., load lock chambers 112A, 112B), for example. Load lock chambers 112A, 112B included in the load lock 112 may be single wafer load locks (SWLL) chambers, or multi-wafer load lock chambers, or even batch load locks, and the like, and possibly combinations thereof.

The factory interface apparatus 108 may be any suitable enclosure, and may have walls (that may include the rear wall 108R, a front wall 108F opposite the rear wall 108R, two side walls, a top wall, and a bottom wall) forming a factory interface chamber 108C. One or more of the walls, such as side walls can include an access door 124 that is opened thus allowing servicing personnel to access the factory interface chamber 108C when one or more components within the factory interface chamber 108C are being serviced (e.g., repaired, changed out, cleaned, calibrated, and the like).

One or more load ports 115 may be provided on one or more of the walls (e.g., front wall 108F) of the factory interface apparatus 108 and may be configured and adapted to receive one or more substrate carriers 116 (e.g., front opening unified pods or FOUPs or the like) thereat. Factory interface chamber 108C may include a load/unload robot 117 (shown as a dotted box 117 in FIG. 1) of conventional construction therein. Load/unload robot 117 may be configured and operational, once the carrier doors 216D (FIG. 2) of the substrate carriers 116 are opened, to extract substrates 205 from the one or more substrate carriers 116 and feed the substrates 205 through the factory interface chamber 108C and into one or more openings (e.g., into the one or more load lock chambers 112A, 112B). Any suitable construction of the opening allowing transfer of substrates 205 between the factory interface chamber 108C and one or more processing chambers 106A-106F (e.g., processing chambers 106A-106F) can be used. Any number of processing chambers and configurations thereof can be used.

In some embodiments, a face clamps 233 (denoted by arrow in FIG. 2) may be included to engage the flange of the substrate carrier 116, such as at two or more locations (e.g., around the periphery). Face clamps 233 operate to seal the flange to the front wall 108F, such as to a load port back plate thereof. Any suitable face clamping mechanism may be used.

In some vacuum embodiments, the transfer chamber 103 may include slit valves at an ingress/egress to the various process chambers 106A-106F. Likewise, load lock chambers 112A, 112B in the load lock 112 may include inner load lock slit valves 223i and outer load lock slit valves 223o as shown in FIG. 2. Slit valves are adapted to open and close when placing or extracting substrates 205 to and from the various process chambers 106A-106F and load lock chambers 112A, 112B. Slit valves may be of any suitable conventional construction, such as L-motion slit valves.

In the depicted embodiment, a factory interface purge apparatus 101 is provided. Factory interface purge apparatus 101 can provide environmental control of the gaseous environment within the factory interface chamber 108C by providing an environmentally-controlled atmosphere thereto. The environmentally-controlled atmosphere can be provided during transfer of substrates 205 through the factory interface chamber 108C and after servicing. In particular, factory interface purge apparatus 101 is coupled to the factory interface chamber 108C and is operational to monitor and/or control one or more environmental conditions within the factory interface chamber 108C.

In some embodiments, and at certain times, the factory interface chamber 108C may receive a purge gas 109 therein. For example, the purge gas 109 can be an inert gas, such as Argon (Ar), Nitrogen (N₂), or helium (He). The purge gas 109 can be supplied from a purge gas supply 119. Purge gas supply 119 may be a container of purge gas 109 and can be coupled to the factory interface chamber 108C by any suitable means, such as one or more conduits including one or more valves 122, such as a variable valve or mass flow controller. Valve 122 allow for the modulation of flow of the purge gas 109 into the factory interface chamber 108C.

The purge gas 109 supplied from the purge gas supply 119 can have a relatively low humidity level therein. In particular, by one suitable measure, the purge gas 109 can have a relative humidity level of 1% or less at room temperature. In some embodiments, and by another measure, the purge gas 109 can have less than 500 ppmV of H₂O, less than 100 ppmV of H₂O, or even less than 10 ppmV of H₂O therein.

In more detail, the factory interface purge apparatus 101 may control at least one of the following within the environment within the factory interface chamber 108C:

1) relative humidity level (% RH at room temperature),
2) an amount of O₂,
3) an amount of inert gas, and
4) an amount of chemical contaminant (e.g., amines, bases, an amount of one or more volatile organic compound (VOC), or the like).

Other environmental conditions of the factory interface chamber 108C may be monitored and/or controlled, such as gas flow rate to or from the factory interface chamber 108C, chamber pressure within the factory interface chamber 108C, or both.

Factory interface purge apparatus 101 further includes a controller 125 including a suitable processor, memory, and electronic peripheral components configured and adapted to receive one or more signal inputs from one or more sensors 130 (e.g., relative humidity sensor, oxygen sensor, chemical component sensor, pressure sensor, flow sensor, temperature sensor, and/or the like) and control flow purge gas 109 through the one or more valves 122 via a suitable control signal from controller 125.

Controller 125 may execute a closed loop or other suitable control scheme. In some embodiments, the control scheme may change a flow rate of the purge gas 109 being introduced into the factory interface chamber 108C. For example, the flow rate of the purge gas 109 being introduced into the factory interface chamber 108C can be responsive to a measured condition from the one or more sensors 130. In another embodiment, the control scheme may determine when to transfer substrates 205 through the factory interface chamber 108C based upon one or more measured environmental conditions then existing within the factory interface chamber 108C.

As will be apparent from the following, and in a broad aspect of the disclosure, the factory interface purge apparatus 101 can include one or more heating members 126 that are configured to heat the purge gas 109 contained in the factory interface chamber 108C. Additionally, factory interface purge apparatus 101 may include a temperature sensor 130 that is configured to measure a temperature of the purge gas 109 in the factory interface chamber 108C. In the depicted embodiment of FIGS. 1-3, the temperature sensor 130 can be provided in the factory interface chamber 108C, such as at or near the operating plane of the load/unload robot 117. However, the temperature sensor 130 can be located anywhere that a suitable estimate correlated to the temperature of the purge gas 109 flowing in the factory interface chamber 108C can be obtained.

The factory interface purge apparatus 101 further comprises a chamber filter assembly 132 configured to filter the purge gas 109 provided to the factory interface chamber 108C from the purge gas supply 119 and also any recirculating purge gas 109 passing through return flow path 235. The chamber filter assembly 132 can be installed in the factory interface chamber 108C or in a return flow path 235 coupled to the factory interface chamber 108C. In the depicted embodiment, the chamber filter assembly 132 can be installed in a way that it forms a plenum chamber 235 in the factory interface chamber 108C. The chamber filter assembly 132 can include In particular, the chamber filter assembly 132 can be of any suitable construction. For example, the chamber filter assembly 132 can include a particulate filter alone, a contaminant filter alone, or both, for example.

When the chamber filter assembly 132 includes a particulate filter, the filter is configured to filter very small particulates from the flow of purge gas 109 such that any particulates contained in the purge gas supply 119, supply conduits, and/or valves 122, and/or return flow path 235 are not exposed to the substrates 205 passing through the factory interface chamber 108C. The chamber filter assembly 132 can be of any suitable construction, and may be a high Efficiency Filtered Air (HEPA) type filter, for example. HEPA filters that can remove greater than 99.97% of particles of 0.3 microns in size or larger can be used. However, various different classes of HEPA filters can be used with even higher particle filtering capabilities of up to 99.9% or higher. Other types of particulate filters that can remove greater than 99.5% of particles of 0.3 microns in median particle size or larger can be used.

If the chamber filter assembly 132 uses a contaminant filter, the contaminant filter can be configured to remove certain chemical compound contaminants from the flow of the purge gas 109, such as acid-forming condensable gases, halogen gases such as Fluorine, Chlorine, and/or Bromine, and bases, for example.

The one or more heating members 126 may be any suitable type configured to heat the purge gas 109 either directly or indirectly. For example, in some embodiments, the one or more heating members 126 may heat the purge gas 109 as it passes by, over, or through the one or more heating members 126. In other embodiments, the one or more heating members 126 may be configured to heat another component that is in thermal contact with the purge gas 109, such as the chamber filter assembly 132.

As shown in FIG. 1-3, the one or more heating members 126 configured to heat the purge gas 109 in factory interface chamber 108C are shown below the chamber filter assembly 132 and located within the factory interface chamber 108C. Purge gas 109 flows into the factory interface chamber 108C through inlet 234. The purge gas 109 is then filtered by chamber filter assembly 132. Subsequent to passing through the chamber filter assembly 132, the purge gas 109 can be heated by the one or more heating members 126. In one embodiments, after a service wherein the access door 124 has been open thus exposing the chamber filter assembly 132 to moist factory air, the access door is closed and the initial flow of purge gas 109 is quite large. Flow is through the factory interface chamber 108C and out through the exhaust 250. The initial goal is to displace the moist air and replace it with purge gas 109. This initial purge can continue until a certain pre-established level of relative humidity (RH) is achieved as sensed by a relative humidity sensor 130. After this, the flow rate of purge gas through the inlet 234 can be diminished to a lower flow level below the initial flow. Now flow of the purge gas 109 may be provided through a return flow path 325, where flow passes in through inflow 236 through return flow path 325 and out from outflow 238 into the plenum chamber 235. In some embodiments a flow valve 340 can be provided in the flow path 325 and can be opened, such as after the initial high-flow purge.

Once the initial high-flow purge is completed, the heating of the purge gas 109 with the one or more heating members 126 can commence. The goal of the heating is to raise the temperature of the purge gas circulating within the factory interface chamber 108C to at least 10° C. above RT, or to 32° C. or more. In further embodiments, it may be desirable to raise the temperature of the purge gas 109 circulating within the factory interface chamber 108C to at least 15° C. above RT, or to 37° C. or more. In the depicted embodiment of FIG. 1-3, the one or more heating members 124 can be one or more resistive electrical heaters. For example, the one or more resistive electrical heaters can comprise a series of filaments, such as parallel filaments extending across the factory interface chamber 108C. Flow of the purge gas 109 across the one or more resistive electrical heaters effectively heats the purge gas 109. Thus, as the purge gas 109 recirculates through the flow path 325, the purge gas 109 continues to be heated with each circulation. It may take 10 minutes to an hour or more to adequately heat the flow of purge gas flow to above the target temperature. Commencing transfer of substrates 205 through the factory interface chamber 108C can be started after a desired gas condition is achieved in the factory interface chamber 108C. For example, the desired gas condition achieved in the factory interface chamber 108C can be a level of relative humidity below as predefined threshold coupled with a temperature above a predetermined threshold. For example, transfer of substrates 205 can be commenced after a level of relative humidity in the factory interface chamber 108C is below 5% RH coupled with a temperature of the factory interface chamber 108C of 32° C. or greater. This can provide conditions that are favorable for substrate transfer and also to allow desorbing of certain chemical compounds from the substrates 205 after processing, such as halogen tetrahalides and particularly bromine tetrahalide.

A temperature sensor 130 is communicatively coupled to the heating controller and configured to provide a signal correlated to a temperature of the purge gas 109. A closed loop control strategy can be used to cause heating until preconditions are met.

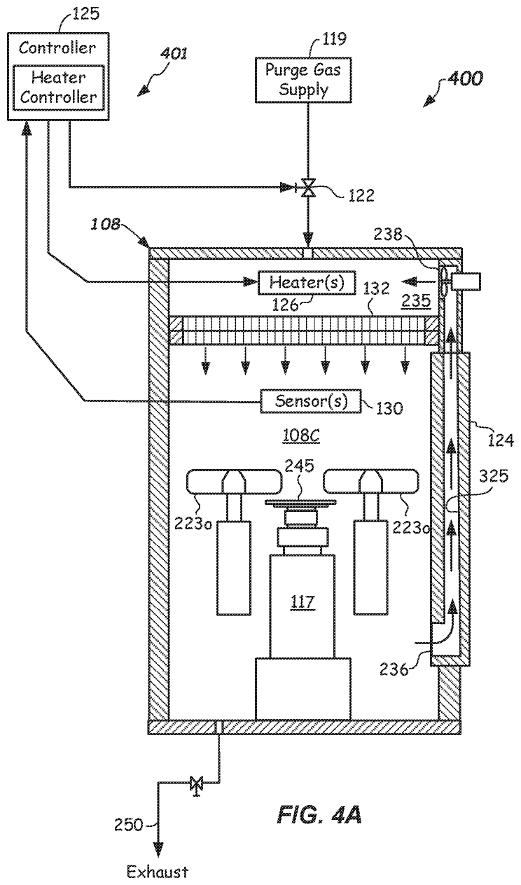

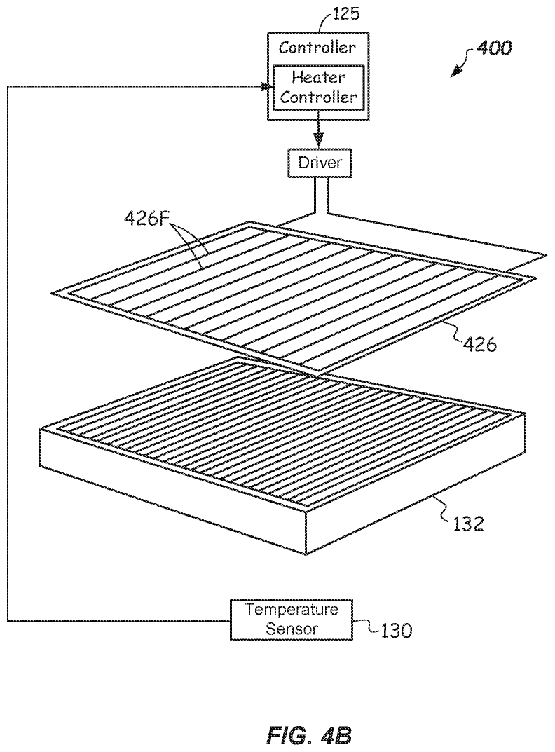

Optionally, the one or more heating members 126 can be located elsewhere. For example, in an alternative embodiment of electronic device manufacturing apparatus 400 shown in FIG. 4A, the one or more heating members 126 configured to heat the purge gas 109 in factory interface chamber 108C can be contained in the plenum chamber 235 that is positioned upstream from the chamber filter assembly 132. The plenum chamber 235 is considered part of the factory interface chamber 108C. The factory interface chamber purge apparatus 401 includes in this embodiment, as shown in FIG. 4B, a heating member 426 configured to heat the purge gas 109 in factory interface chamber 108C by heating the purge gas 109 in the plenum chamber 235 prior to the purge gas 109 entering into the chamber filter assembly 232. The heating can be accomplished by a plurality of resistive filaments 426F of the heating element 426. Thus, the heating element 426 is provided in a flow path upstream of the chamber filter assembly 232. The heating element 426 can be spaced a sufficient distance away from the chamber filter assembly 232 so as to not damage the chamber filter assembly 232. Heating element 426 can generate a power of between about 1,000 watts and 3,000 watts, for example. Other suitable power levels can be used.

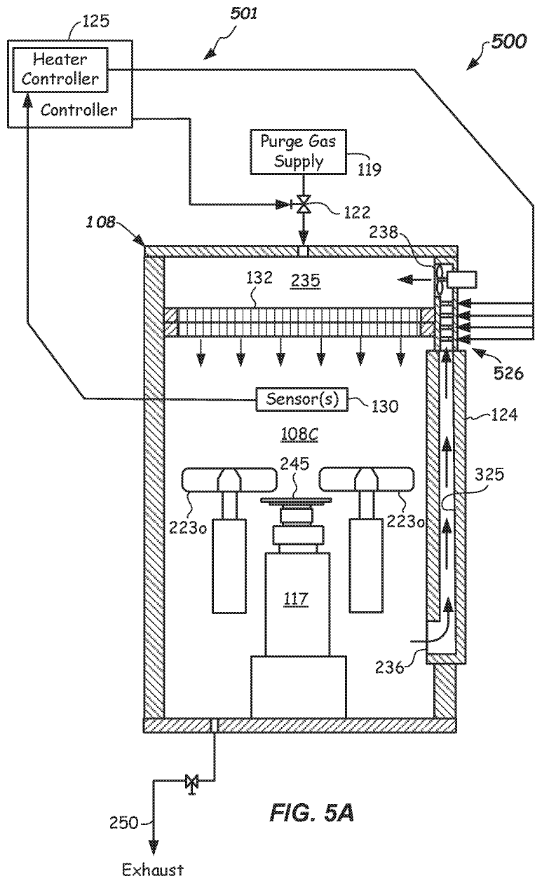

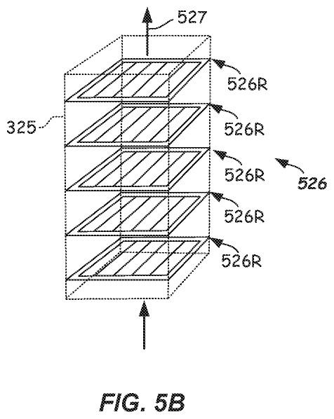

In another embodiment of electronic device manufacturing apparatus 500, the one or more heating members 526 of the factory interface purge apparatus 501 can be contained in gas flow path 325 coupled to the factory interface chamber 108C. For example, in one embodiment, as shown in FIGS. 5A-5B, the one or more heating members 526 can be contained in flow return path 325 configured to provide return flow (indicated by arrow 527) of the purge gas 109 to the chamber filter assembly 132. For example, a series of small resistive heating elements 526R, such as including parallel resistive filaments can be staged along the return flow path 325. Each of the small resistive heating elements 526R can generate a power of between about 200 watts and 600 watts, for example. Five small resistive heating elements 526R are shown. However, more or less numbers of small resistive heating elements 526R can be used.

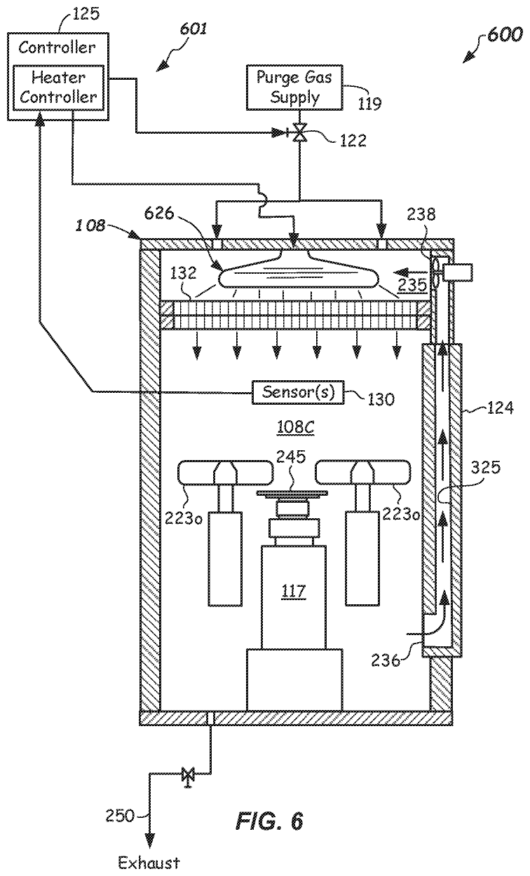

In another embodiment, a factory interface purge apparatus 600 is provided as best shown in FIG. 6. In this embodiment, the one or more heating members 626 are configured to heat a component that is in thermal contact with the purge gas 109. For example, the one or more heating members 626 can reside in the plenum chamber 235 and can heat the chamber filter assembly 132 by way of radiant heating. The one or more heating members 626 can be one or more infrared heating elements. For example, the one or more infrared heating elements can be can be one or more infrared bulbs or tubular infrared lamps and can emit infrared radiation in wavelengths ranging from about 1.5 μm to about 8 μm. Then total power output of the one or more heating members 626 can be between 1,000 watts and 3,000 watts, for example.

Each of the factory interface purge apparatus 101, 401, 501, and 601 described herein may, in one or more embodiments, monitor relative humidity (RH) by sensing RH in the factory interface chamber 108C with a relative humidity sensor 130. Any suitable type of relative humidity sensor may be used, such as a capacitive-type or other sensor. The RH sensor 130 may be located within the factory interface chamber 108C or within a conduit connected to the factory interface chamber 108C, such as with the return flow path 325, for example.

Controller 125 may monitor RH, and when a measured RH signal value provided to the controller 125 is above a predefined low RH threshold value, carrier doors 216D of the one or more substrate carriers 116 coupled to load ports 115 of the factory interface 108 will stay closed. Likewise, slit valve 223o of the load lock 112 may be kept closed until the measured RH signal level below the predefined low RH threshold value is achieved. The predefined relative humidity level can be less than 10% at room temperature (RT), less than 5% at RT, less than 2% at RT, or even less than 1% at RT in some embodiments.

Other measures of humidity control may be measured and used as the predefined low humidity threshold, such as ppmV of H₂O being below a predefined level. In one or more embodiments, the pre-defined low threshold of a humidity level can be less than 1,000 ppmV H₂O, less than 300 ppmV H₂O, less than 100 ppmV H₂O, or even less than 50 ppmV H₂O contained therein in some embodiments. The pre-defined low threshold can be based upon a level of moisture that is tolerable for the particular process being carried out on the substrates 205.

The RH level may be lowered by flow of a suitable amount of a purge gas 109 from the purge gas supply 119 into the factory interface chamber 108C. As described herein, the purge gas 109 may be an inert gas from the purge gas supply 119 may be argon, nitrogen gas (N₂), helium, or mixtures thereof. If exposure to oxygen is tolerated for the particular process being carried out on the substrates 205, then in some embodiments clean dry air can be used as the purge gas 109. A supply of dry nitrogen gas (N₂) may be quite effective at controlling environmental conditions within the factory interface chamber 108C. Compressed bulk gases having low H₂O levels (as described herein) may be used as the purge gas supply 119. The supplied purge gas 109 from the purge gas supply 119 may fill the factory interface chamber 108C during substrate processing when substrates 205 are being transferred through the factory interface chamber 108C. Further, during the flow of the purge gas 109 from the purge gas supply 119, the heating members 126, 426, 526, 626 can be operated in order to heat the purge gas 109.

In some instances, flow rates of the purge gas 109 provided into the factory interface chamber 108C during initial purge (i.e., following closing the access door 124) may be provided by adjusting the valve 122 coupled to the purge gas supply 119 responsive to control signals from controller 125. Flow rates of purge gas 109 ranging from 500 slm and 750 slm may be provided during these initial purge stage. During the initial purge stage, the heating elements 126, 426, 526, 626 may not be operated. Flow rates can be monitored by a suitable flow sensor (not shown) on a delivery line.

Flow of the purge gas (e.g., N₂ or other purge gas) into the factory interface chamber 108C can be operative to lower the relative humidity (RH) level within the factory interface chamber 108C to below a first predefined threshold level. Once the first predefined threshold value is met, the one or more heating members 126, 426, 526, 626 can be turned on to heat the purge gas 109 in the factory interface chamber 108C. The heating with the one or more heating members 126, 426, 526, 626 can continue until a second relative humidity threshold is achieved that is lower than the first predefined threshold. Optionally, the one or more heating members 126, 426, 526, 626 can be operated until a target temperature threshold is achieved. For example, the target threshold temperature can be 10° C. above room temperature (RT), 15° C. above room temperature (RT), or even 20° C. above room temperature (RT), or more.

In one or more embodiments, the one or more sensors 130 includes a temperature sensor that is configured and adapted to sense a temperature of the purge gas 109 within the factory interface chamber 108C. In some embodiments, the temperature sensor 130 may be placed in close proximity to a path of the substrate 205 as it passes through the factory interface chamber 108C on the load/unload robot 117. In some embodiments, the temperature sensor 130 may be a thermocouple or thermistor. Other suitable temperature sensor types can be used.

Heating the purge gas 109 helps to ensure that the chamber filter assembly 132 has any moisture contamination resulting from the servicing rapidly removed therefrom so that the processing of substrates 205 can again commence after the service interval in completed. Thus, the time to resume processing of substrates 205 after a service interval can be dramatically lowered. For example, the time to processing of substrates 205 from closure of the access door 124 can be less than 10 hours, less than 5 hours, or even less than 3 hours, for example.

Furthermore, once processing of substrates 205 has again commenced substrates 245, the heating of the purge gas 109 has the further effect of allowing chemical compounds absorbed on the substrates 205 to be more rapidly desorbed in the low humidity environment. Thus, substrates 205 exiting the load lock chambers 112A, 112B and passing through the factory interface chamber 108C are exposed to not only a suitably low humidity environment, but a heated environment that aids in desorbing certain chemical compounds such as silicon tetrahalides, and particularly bromine tetrahalide.

In some embodiments where low oxygen (O₂) levels are desired for substrate processing, environmental preconditions may be met, for example, when a measured oxygen (O₂) level in the factory interface chamber 108C falls below a predefined oxygen threshold level. Oxygen (O₂) level may be sensed by the one or more sensors 130, such as by an oxygen sensor. If the measured oxygen (O₂) level falls below a predefined oxygen threshold level (e.g., less than 50 ppm O₂, less than 10 ppm O₂, less than 5 ppm O₂, or even less than 3 ppm O₂, or even lower), then exchange of substrates 205 may take place through the factory interface chamber 108C. Other suitable oxygen level thresholds may be used, depending on the processing taking place. As before, once an initial O₂ threshold is met, after an initial post-service purge is accomplished, the heating elements 126, 526, 526, 626 can be operated to achieve an additional threshold, such as O₂ level, and/or RH level and/or temperature of the purge gas 109. If the predefined oxygen threshold level in the factory interface chamber 108C is not met, the controller 125 will initiate a control signal to the valve 122 coupled to the purge gas supply 119 and flow purge gas 109 into the factory interface chamber 108C until the predefined low oxygen threshold level is met, as determined by the controller 125 receiving signal from an O₂ sensor 130.

Once the predefined low oxygen threshold level is met and a second threshold of RH or temperature of the purge gas 109 in the factory interface chamber 108C is achieved, the carrier door 216D and/or the load lock slit valves 2230 of the one or more load lock chambers 112A, 112B may be opened. This helps to ensure that substrates 205 exiting the load lock chambers 112A, 112B and passing through the factory interface chamber 108C are exposed to not only relatively low oxygen levels, but also a suitably heated environment that can assist in desorbing certain chemical compounds from the substrates 205 after processing.

In the depicted embodiments described herein, in addition to the factory interface chamber purge apparatus 101, 401, 501, 601, the electronic device processing apparatus 100, 400, 500, 600 may further include a carrier purge apparatus 136. Carrier purge apparatus 136 includes a purge gas supply (e.g., purge gas supply 119) coupled to the carriers 116. In particular, the purge gas 109 may be provided via a conduit 146 and one or more valves 122 configured and adapted to control flow of the purge gas 109 from the purge gas supply 119. Purge gas 109 may be provided to purge the interior 247 (FIG. 2) of the carrier 116 prior to opening the carrier door 216D. Carrier door 216D can be opened when the environmental conditions are met within the factory interface chamber 108C, such as when the RH threshold and temperature threshold are met.

In some embodiments, the factory interface chamber purge apparatus 101, 401, 501, 601 can be configured to supply a purge gas comprising clean dry air to the chamber filter assembly 132 when the access door 124 is open. The flow of the purge gas comprising clean dry air can be initiated just prior to opening the access door 124 in order to flush any inert gas from the factory interface chamber 108C and provide a suitable breathable air environment for entry of service personnel upon opening access door 124. The flow of clean dry air may continue to flow for the entire time that the access door 124 is open. Flowing the purge gas comprising clean dry air through the chamber filter 132 when the access door 124 is open can minimize contamination of the chamber filter 132 by humidity (moisture) that is contained in the ambient air entering into the factory interface chamber 108C through the access door 124 from the factory environment outside of the factory interface 108.

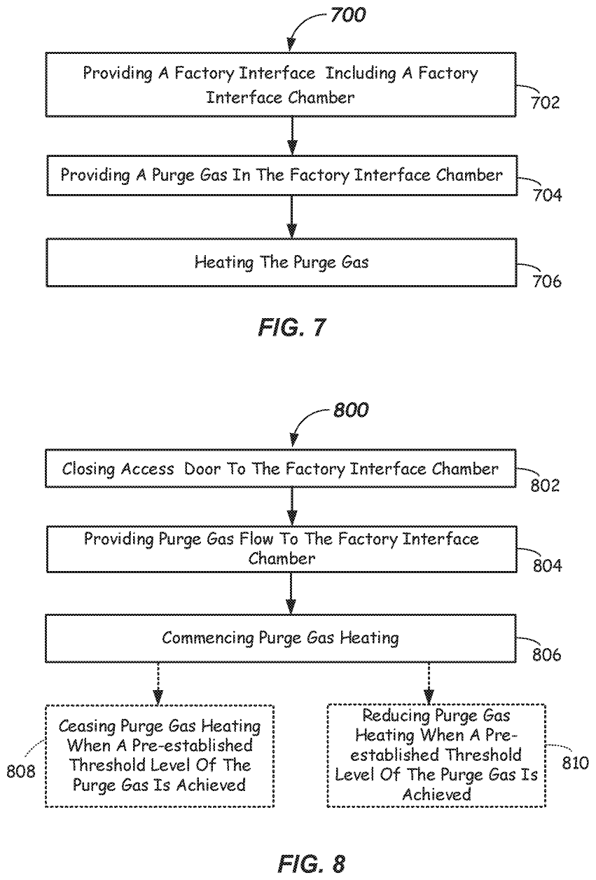

When the access door 124 is closed after servicing), a purge control method 700 of the disclosure may be practiced. The method 700, as best shown in FIG. 7 includes, in 702, providing a factory interface chamber (e.g., factory interface chamber 108C), and, in 704, providing a purge gas (e.g., purge gas 109) in the factory interface chamber. Flow of purge gas 109 can be from any suitable purge gas supply 119. Once a suitable threshold level of the purge gas 109 in the factory interface chamber 108C is achieved, such as a first low RH threshold, then, in 706, heating of the purge gas 109 can commence. The heating can continue until a second threshold is achieved, such as a second low RH level threshold that is below the first threshold or a temperature threshold, or both. In some embodiments, the level of heat can be continuous, but at a lower power level once a suitable threshold is met.

According to another embodiment, a purge control method 800 adapted to be used after a service interval is completed is described. The purge control method 800 includes in 802, closing the access door (e.g., access door 124) to the factory interface chamber (e.g., factory interface chamber 108C). In 804, the method 800 includes providing purge gas flow to the factory interface chamber. The providing purge gas flow in 804 can be initiated after closure of the access door 124 when the purge gas is an inert gas, such as N2. Optionally, the providing of the purge gas can be before opening the door 124 and continuously during the servicing interval when the access door 124 is opened, when the purge gas 109 is clean dry air.

The method 800 further includes commencing purge gas heating in 806. Purge gas heating can be initiated after an initial high-flow purge is accomplished. The point where the heating elements 126, 426, 526, 626 are powered to heat the purge gas 109 can be upon achieving a first low RH level threshold in the factory interface chamber 108C, for example.

The method 800 can further optionally include, in 808, ceasing purge gas heating when a desired threshold level of the purge gas 109 is achieved. For example, the desired threshold level can be a second low RH level or a temperature of the purge gas 109, or both. Optionally, in 810, rather than ceasing purge heating, a level of purge heating can be reduced when a desired threshold level of the purge gas 109 is achieved (e.g., RH level, temperature, or both).

As will be apparent from the foregoing, the use of the factory interface chamber purge apparatus 101, 401, 501, 601 described herein may be operative to control the environment within the factory interface chamber 108C to meet certain environmental conditions, but may also allow the processing of substrates 205 to resume much more rapidly after a service interval by ensuring that any moisture contamination of the chamber filter 132 is minimized and/or readily removed via providing suitable purge gas heating.

Accordingly, after servicing of a component in the factory interface chamber 108C, time to resume processing of substrates 205 may be appreciably shortened, such as to about less than about 10 hours, less than about 5 hours, less than 4 hours, less than 2 hours, or even less than about 1 hour after access door 124 closure.

The foregoing description discloses only example embodiments of the disclosure. Modifications of the above-disclosed apparatus and methods that fall within the scope of the disclosure will be readily apparent to those of ordinary skill in the art. Accordingly, it should be understood that other embodiments may fall within the scope of the disclosure, as defined by the claims.

The invention claimed is:

1. A factory interface purge apparatus, comprising:
a factory interface chamber including a purge gas; and one or more heating members configured to heat the purge gas in factory interface chamber.

2. The factory interface purge apparatus of claim 1, further comprising:
an environmental control system coupled to the factory interface chamber and configured to supply the purge gas to control one or more environmental conditions within the factory interface chamber during substrate transfer through the factory interface chamber.

3. The factory interface purge apparatus of claim 1, wherein the one or more heating members are contained within the factory interface chamber.

4. The factory interface purge apparatus of claim 1, further comprising a chamber filter assembly configured to filter the purge gas provided to factory interface chamber.

5. The factory interface purge apparatus of claim 4, wherein the one or more heating members are contained in a plenum chamber positioned upstream from the chamber filter assembly.

6. The factory interface purge apparatus of claim 4, wherein the one or more heating members are contained in gas flow path coupled to the factory interface chamber.

7. The factory interface purge apparatus of claim 4, wherein the one or more heating members are contained in flow return path configured to provide return gas flow to the chamber filter assembly.

8. The factory interface purge apparatus of claim 1, wherein the one or more heating members are resistive heating elements.

9. The factory interface purge apparatus of claim 1, wherein the one or more heating members are configured to heat a component that is in thermal contact with the purge gas.

10. The factory interface purge apparatus of claim 1, wherein the one or more heating members are infrared heating elements.

11. The factory interface purge apparatus of claim 1, wherein the purge gas is an inert gas or clean dry air.

12. The factory interface purge apparatus of claim 11, wherein the purge gas comprises clean dry air or an inert gas selected from a group consisting of argon gas, N2 gas, helium gas.

13. The factory interface purge apparatus of claim 1, configured to heat the purge gas contained in the factory interface chamber to a temperature of at least 10° C. above room temperature.

14. The factory interface purge apparatus of claim 1, configured to heat the purge gas contained in the factory interface chamber to a temperature of at least 15° C. above room temperature.

15. The factory interface purge apparatus of claim 1, comprising a heating controller configured to provide a drive current signal to cause heating of the one or more heating members.

16. The factory interface purge apparatus of claim 15, comprising a temperature sensor communicatively coupled to the heating controller and configured to provide a signal correlated to a temperature of the purge gas.

17. The factory interface purge apparatus of claim 1, comprising an environmental control system configured to control one or more environmental conditions within the factory interface chamber, comprising:
a relative humidity level, an amount of O₂,
an amount of purge gas, or
an amount of chemical contaminant, within the factory interface chamber.

18. The factory interface purge apparatus of claim 1, comprising a humidity sensor configured to sense a relative humidity level within the factory interface chamber.

19. The factory interface purge apparatus of claim 1 comprising an oxygen sensor configured to sense an oxygen level within the factory interface chamber.

20. A chamber filter purge apparatus, comprising:
a factory interface chamber including an access door;
a chamber filter assembly configured to filter a purge gas provided in the factory interface chamber; and
a purge gas heating apparatus comprising one or more heating members configured to heat the purge gas provided to the chamber filter assembly.

21. A purge control method, comprising:
providing a factory interface chamber having an access door configured to provide personnel servicing access into the factory interface chamber;
closing the access door;
providing flow of a purge gas to the factory interface chamber; and
commencing heating of the purge gas.

22. The purge control method of claim 21, comprising ceasing or reducing purge gas heating when a pre-established threshold level of the purge gas is reached.

23. The purge control method of claim 22, wherein the pre-established threshold level is a relative humidity level in the factory interface chamber.

24. The purge control method of claim 22, wherein the pre-established threshold level is a temperature of the purge gas in the factory interface chamber being above 32° C.

25. The purge control method of claim 22, wherein the pre-established threshold level is a temperature of the purge gas in the factory interface chamber being above 37° C.

26. The purge control method of claim 21, wherein the providing the flow of the purge gas further comprises:
initiating high-volume purge of the factory interface chamber after access door closure; and
transition to low-volume purge of the factory interface chamber after a pre-established threshold limit is reached.

27. The purge control method of claim 26, wherein resumption of substrate transfer after closure of the access door occurs only after a predefined low level of relative humidity in the factory interface chamber is reached.

28. The purge control method of claim 26, wherein resumption of substrate transfer after closure of the access door occurs only after both a predefined threshold level of temperature and a predefined low level of relative humidity in the factory interface chamber are reached.
